(19) United States
(12) Patent Application Publication
(10) Pub. No.: US 2025/0118696 A1
(43) Pub. Date: Apr. 10, 2025

(54) SOLDER AND SEMICONDUCTOR DEVICE

(71) Applicant: MINEBEA POWER SEMICONDUCTOR DEVICE INC., Hitachi-shi, Ibaraki (JP)

(72) Inventors: Osamu IKEDA, Tokyo (JP); Yukihiro KUMAGAI, Tokyo (JP); Yuichiro BANNO, Tokyo (JP)

(21) Appl. No.: 18/729,973

(22) PCT Filed: Dec. 13, 2022
(86) PCT No.: PCT/JP2022/045811

§ 371 Date: Jul. 18, 2024

(30) Foreign Application Priority Data
Jan. 20, 2022 (JP) 2022-007183

(51) Int. Cl. H01L 23/00

(52) U.S. Cl. CPC H01L 24/29; H01L 24/05; H01L 2224/05655; H01L 2224/29111; H01L 2224/29113; H01L 2224/29116; H01L 2224/29117; H01L 2224/2912; H01L 2224/29147; H01L 2224/2916

(57) ABSTRACT

Provided is a technique capable of improving the connection reliability of solder connection of a semiconductor device under a high temperature environment and reducing the wetting and spreading defect of the solder. As a means therefor, a solder containing Cu at a content of 3 to 9 wt %, Sb at a content of 6.7 to 9.6 wt %, and Sn and added with one or a plurality of types of elements among Fe of 0.004 to 0.01 wt %, Bi of 0.002 to 0.04 wt %, Pb of 0.01 to 0.09 wt %, and As of 0.0125 to 0.02 wt % is used as a solder to bond a semiconductor element.

### TECHNICAL FIELD

The present invention relates to a solder and a semiconductor device using the same, and particularly to a solder used to bond a power semiconductor element that is required to have high heat resistance and high reliability.

### BACKGROUND ART

A power module using SiC, IGBT, or the like is mounted on an inverter that controls a large-output motor such as a motor for electric railroad, power generation, or an electric vehicle/hybrid electric vehicle (EV/HEV). In recent years, since the increase in power density and miniaturization have been progressing and the amount of current flowing through each power semiconductor element has been increasing, there is a need for a highly heat-resistant solder.

As such a highly heat-resistant solder alloy, for example, Patent Document 1 (Japanese Unexamined Patent Application Publication No. 2009-255176) describes that any one or two or more types of elements among Co, Fe, Mo, Cr, Ag, and Bi are added to a solder composition in which Sb is 10 to 40 wt %, Cu is 0.5 to 10 wt %, and the remaining is Sn in order to improve the mechanical strength, and one or more types of Ge and Ga are further added as oxidation suppressing elements.

In addition, Patent Document 2 (Japanese Unexamined Patent Application Publication No. 2005-118800) describes, as a high-temperature solder for lamps, a high-melting point solder having a composition in which Sb is 5 to 40 wt %, Cu is 10 wt % or less, and the remaining is Sn and having a solidus temperature of 235° C. or higher.

### RELATED ART DOCUMENTS

### Patent Documents

Patent Document 1: Japanese Unexamined Patent Application Publication No. 2009-255176
Patent Document 2: Japanese Unexamined Patent Application Publication No. 2005-118800

### SUMMARY OF THE INVENTION

### Problems to be Solved by the Invention

In the technique described in Patent Document 1, since the solder contains Sb of 10 to 40 wt %, a R phase included in the solder precipitates in a large amount and the solder hardens, and thus there is a problem that the semiconductor element is cracked when thermal stress is applied. In addition, there is another problem that the precipitation of a large amount of hard R phase reduces the stress buffering ability of the solder and accelerates crack development in the solder, thereby degrading the reliability of the solder. Furthermore, in the assembly of the semiconductor device, there is a problem that the wettability and spreadability of the solder degrade due to the inclusion of Sb, thereby increasing the insufficiency in wettability and spreadability. However, only the addition of an element for preventing oxidation at the time of bonding is considered here, and the improvement of wettability and spreadability itself is not considered.

In the solder described in Patent Document 2 as well, as in Patent Document 1, there are problems of cracking of the semiconductor element and crack development in the solder when the amount of added Sb is within the range of 10 to 40 wt %. Also, when Sb constituting the solder is 5 wt % or more and less than 10 wt %, the cracking of the semiconductor element can be prevented, but the problem of insufficient wettability and spreadability cannot be solved because the solder contains Sb. Patent Document 2 describes that the solderability is improved by adding one or two or more types selected from Ag and Bi at 1 wt % or less in total and one or two types selected from P, Ge, and Ga at 0.001 to 0.05 wt % in total. However, when Ag is added, an Ag3Sn compound precipitates in the parent phase and the solder parent phase hardens, and thus there is a risk of cracking of the semiconductor element or breakage of the semiconductor electrode film. In addition, Bi is known as an element that is likely to segregate at the interface of the bonding portion at the time of solder bonding, and thus there is a risk that the large additive amount of Bi may degrade the reliability of the interface of the bonding portion. Here, although the solderability is improved by suppressing the oxidation of the solder by adding P, Ge, and Ga, the degradation in wettability and spreadability due to the addition of Sb cannot be improved by suppressing the oxidation because the degradation is not due to the influence of the solder oxidation but is caused by the change in surface tension due to the addition of Sb.

An object of the present invention is to provide a technique capable of improving the connection reliability of solder connection of a semiconductor device under a high temperature environment and reducing a wetting and spreading defect of the solder.

Other objects and novel features will become apparent from the description of this specification and the accompanying drawings.

### Means for Solving the Problems

An outline of a typical embodiment disclosed in this application will be briefly described as follows.

A solder according to an embodiment contains Cu at a content of 3 to 9 wt %, Sb at a content of 6.7 to 9.6 wt %, and Sn, and is added with one or a plurality of types of elements among Fe of 0.004 to 0.01 wt %, Bi of 0.002 to 0.04 wt %, Pb of 0.01 to 0.09 wt %, and As of 0.0125 to 0.02 wt %.

### Effects of the Invention

According to the present invention, it is possible to provide a technique capable of improving the connection reliability of solder connection of a semiconductor device under a high temperature environment and reducing the wetting and spreading defect of the solder.

### BRIEF DESCRIPTIONS OF THE DRAWINGS

FIG. 1 is a schematic view illustrating a cross section of a bonding portion of a semiconductor element using a solder according to the first embodiment.

FIG. 2 is an Sn—Sb binary phase diagram.

FIG. 3 is a graph illustrating a relationship between the Fe content and the occurrence rate of a wetting and spreading defect.

FIG. 4 is a graph illustrating a relationship between the Bi content and the occurrence rate of the wetting and spreading defect.

FIG. 5 is a graph illustrating a relationship between the Pb content and the occurrence rate of the wetting and spreading defect.

FIG. 6 is a graph illustrating a relationship between the As content and the occurrence rate of the wetting and spreading defect.

FIG. 7 is a diagram illustrating a relationship between the holding time at 200° C. and the disappearance thickness of an Ni-based electrode.

FIG. 8 is a schematic view illustrating a cross section of a semiconductor device according to the second embodiment.

### DETAILED DESCRIPTION OF PREFERRED EMBODIMENTS

Hereinafter, embodiments of the present invention will be described in detail with reference to the drawings. In all the drawings for describing the embodiments, members having the same function are denoted by the same reference characters, and repetitive description thereof will be omitted. In addition, in the embodiments, descriptions of the same or similar parts will not be repeated in principle unless particularly necessary.

### <Room for Improvement>

The temperature of the bonding portion of a power semiconductor element exceeds 150° C. due to heat generation of the element in some cases. Therefore, for example, when Sn-3Ag-0.5Cu (wt %) or the like that is an Sn-based solder is used to bond the semiconductor element, a reaction progresses between the solder and the Ni-based electrode of the semiconductor element under high temperature, and thus there is a risk that the Ni-based electrode may disappear and the semiconductor element may be peeled off. In addition, when the maximum temperature of the bonding portion exceeds 150° C., a load is applied on the solder bonding portion in a power cycle in which heat generation/cooling of the semiconductor element is repeated due to ON/OFF of current flow, and thus there is a risk that the grain boundary fracture of the solder may be accelerated and the life is greatly reduced.

To address this problem, Patent Document 1 describes a solder composition in which Sb is 10 to 40 wt %, Cu is 0.5 to 10 wt %, and the remaining is Sn. In addition, Patent Document 2 describes a high-melting point solder having a composition in which Sb is 5 to 40 wt %, Cu is 10 wt % or less, and the remaining is Sn and having a solidus temperature of 235° C. or higher.

However, in the technique described in Patent Document 1, the solder contains Sb of 10 to 40 wt % and the solder alloy hardens, and thus there are a problem that the semiconductor element is cracked when thermal stress is applied and a problem that crack development is accelerated to degrade the reliability.

In addition, the technique described in Patent Document 2 includes the range of Sb of 5 wt % or more to less than 10 wt % in which the solder is relatively soft and can suppress cracking of the semiconductor element, but measures to suppress a wetting defect of the solder associated with the degradation in the wettability and spreadability of the solder due to the inclusion of Sb are not sufficient, and the wetting and spreading defect of the solder cannot be reduced to a desired rate at the time of mass production. In mass production of semiconductor devices, it is not preferable to allow defects exceeding 1% from the viewpoint of prime cost reduction, and a technique for positively suppressing the degradation in wettability and spreadability associated with the addition of Sb is required.

As described above, there is room for improvement in the solder used for electrical connection of the power semiconductor element. Therefore, in each embodiment of this application, measures are taken to fill the above-described room for improvement. Hereinafter, a technical idea in the embodiments in which such measures are taken will be described.

### First Embodiment

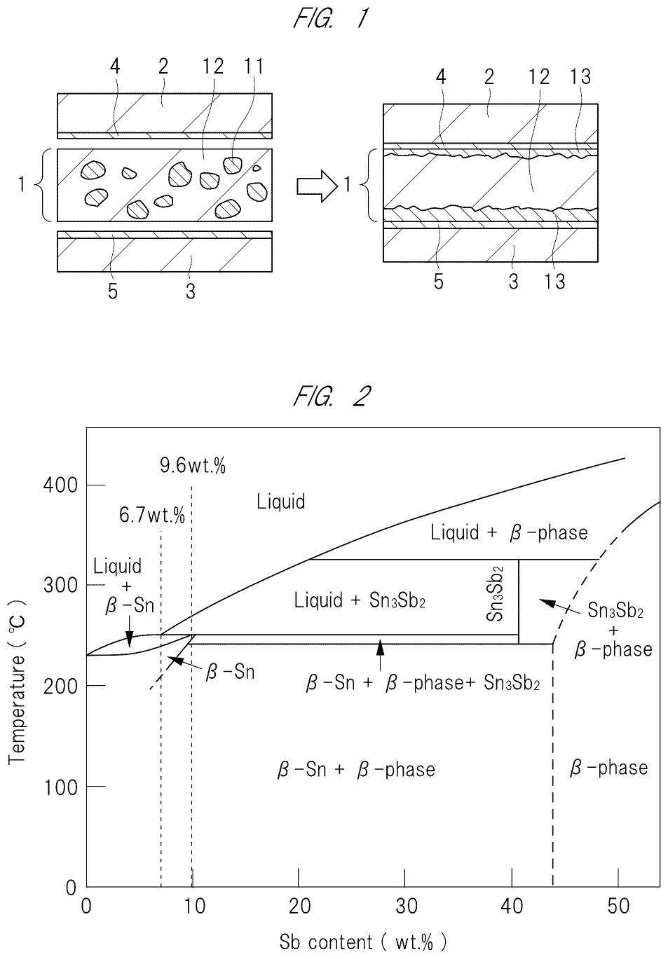

Hereinafter, the present embodiment will be described with reference to FIG. 1 to FIG. 7.

A solder of the present embodiment contains Cu (copper) at a content of 3 to 9 wt %, Sb (antimony) at a content of 6.7 to 9.6 wt %, Fe (iron) at a content of 0.004 to 0.01 wt %, and Sn (tin) and inevitable impurities that account for the remaining percent.

Here, Cu is added to the solder at 3 to 9 wt %. Therefore, when the semiconductor element and the electrode are bonded to each other using the solder, Cu₆Sn₅ contained in the solder crystallizes and precipitates adjacent to a nickel (Ni)-based electrode (Ni, Ni—V, Ni—P, Ni—B, etc.) on the side of the semiconductor element, as illustrated on the right side of FIG. 1. FIG. 1 is a cross-sectional view illustrating a state in which a substrate 3 including an electrode 5 formed by applying Ni-based metallization on the upper surface and a semiconductor element (semiconductor chip) 2 including an Ni-based electrode 4 on the lower surface are bonded to each other using a solder 1. Here, the substrate 3 includes the electrode 5, but the solder may be directly connected to the substrate 3 without the electrode 5 on the substrate 3. The solder 1 of the present embodiment contains particles of a Cu₆Sn₅ compound in the parent phase 12 of the Sn-based solder before bonding. After bonding, a compound layer 13 composed of Cu₆Sn₅ or a (Cu, Ni)₆Sn₅ compound in which Cu is slightly replaced with Ni crystallizes and precipitates on the surfaces of the solder 1, that is, on each surface on the side of the semiconductor element 2 and the side of the substrate 3.

Because of the presence of the compound layer 13, when a semiconductor device including the semiconductor element 2 and the substrate 3 bonded to each other via the solder 1 is held under high temperature of 150° C. or higher, it is possible to suppress the Ni-based electrode 4 of the semiconductor element 2 from reacting with Sn in the solder 1 and being consumed. Namely, the compound layer 13 functions as a barrier layer between the Ni-based electrode 4 and the solder 1.

If the addition of Cu in the solder is less than 3 wt %, the effect of suppressing the reaction of the Ni-based electrode 4 when the semiconductor device is held at 150° C. or higher cannot be sufficiently obtained. On the other hand, if Cu is added to the solder at more than 9 wt %, the amount of Cu₆Sn₅ that is not melted in the temperature range of 250 to 400° C. for bonding the semiconductor element increases excessively, thereby making it difficult to discharge voids at the time of bonding.

In addition, by adding Sb to the solder at 6.7 to 9.6 wt %, the grain boundary fracture of the solder due to thermal shock and the power cycle can be suppressed, thereby making it possible to prolong the solder life. In order to suppress the grain boundary fracture of the solder, it is necessary to make the solder soft and easy to deform and to relax stress to the grain boundary such that the grain boundary is not fractured when the stress is generated in the solder bonding portion under high temperature of 150° C. or higher. In order to improve the deformability of the solder under high temperature, it is important to dissolve Sb in Sn. However, if Sb is added to the solder at more than 9.6 wt %, an Sn₃Sb₂ compound precipitates even after the solder is solidified as can be seen from the Sn—Sb binary phase diagram in FIG. 2, and crystal grains of solidified β-Sn cannot be coarsened and the solder hardens. When the solder hardens in a temperature range lower than room temperature and a large stress is generated in the semiconductor element, the stress buffering ability of the solder cannot be expected and thus there is a risk of element cracking. Since the solder described in Patent Documents 1 and 2 contains Sb at 10 wt % or more, there is a risk of such element cracking. On the other hand, if Sb is added at less than 6.7 wt %, the amount of added Sb is insufficient, and thus there is a risk that sufficient resistance against thermal shock and the power cycle may not be obtained in the high temperature range of 150° C. or higher.

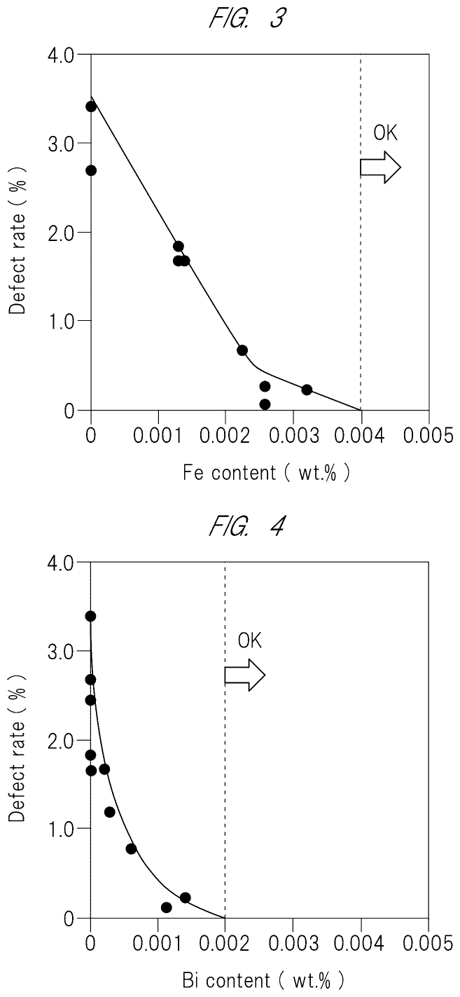

In addition, by adding Fe to the solder at 0.004 to 0.01 wt %, it is possible to suppress the wetting and spreading defect of the solder at the time of mass production. FIG. 3 illustrates a relationship between the Fe content and the occurrence rate of the wetting and spreading defect at the time of mass production. The vertical axis of the graph illustrated in FIG. 3 represents the occurrence rate of the wetting and spreading defect of the solder, and the horizontal axis represents the Fe content. When measuring the relationship between the occurrence rate of the wetting and spreading defect of the solder and the content of Fe shown in FIG. 3 by an experiment, the inventors judged that the wetting and spreading defect occurred when an unsoldered region was 5% or more of the area of the semiconductor element. The same criterion for judging the wetting and spreading defect applies to FIG. 4 to FIG. 6 used in the following description. The defect occurrence rate decreases as the Fe content increases, and the wetting and spreading defect is suppressed at 0.004 wt % or more. On the other hand, when Fe is added at more than 0.01 wt %, an Fe—Sn compound precipitates in the parent phase of the solder and the solder hardens, and thus there is a risk that the semiconductor element may be cracked or the electrode film may be broken due to thermal shock and the power cycle.

Here, the solder containing Fe in addition to Cu, Sb, and Sn has been described, but the solder of the present embodiment may contain Bi (bismuth), Pb (lead), or As (arsenic) at the content described below instead of Fe. Namely, the solder of the present embodiment may contain one or a plurality of types of elements among Fe, Bi, Pb, and As. When the solder is supplied, the solder alloy may be in a form such as a sheet or a wire, or may be in a paste form in which powdered solder is kneaded together with a flux or the like.

The solder of the present embodiment may contain Bi (bismuth) at a content of 0.002 to 0.04 wt % in addition to Cu of 3 to 9 wt %, Sb of 6.7 to 9.6 wt %, and Sn.

By adding Bi to the solder at 0.002 to 0.04 wt %, it is possible to suppress the wetting and spreading defect of the solder at the time of mass production. FIG. 4 illustrates a relationship between the Bi content and the occurrence rate of the wetting and spreading defect of the solder at the time of mass production. The vertical axis of the graph illustrated in FIG. 4 represents the occurrence rate of the wetting and spreading defect of the solder, and the horizontal axis represents the Bi content. As illustrated in FIG. 4, the defect occurrence rate decreases as the Bi content increases, and the wetting and spreading defect is suppressed at 0.002 wt % or more. On the other hand, when Bi is added at more than 0.04 wt %, Bi segregates in the vicinity of the interface of the bonding portion at the time of bonding, and thus there is a risk that the grain boundary fracture of the solder parent phase and the fracture of the interface of the bonding portion are accelerated due to thermal shock and the power cycle, thereby impairing reliability.

In addition, the solder of the present embodiment may contain Pb at a content of 0.01 to 0.09 wt % in addition to Cu of 3 to 9 wt %, Sb of 6.7 to 9.6 wt %, and Sn.

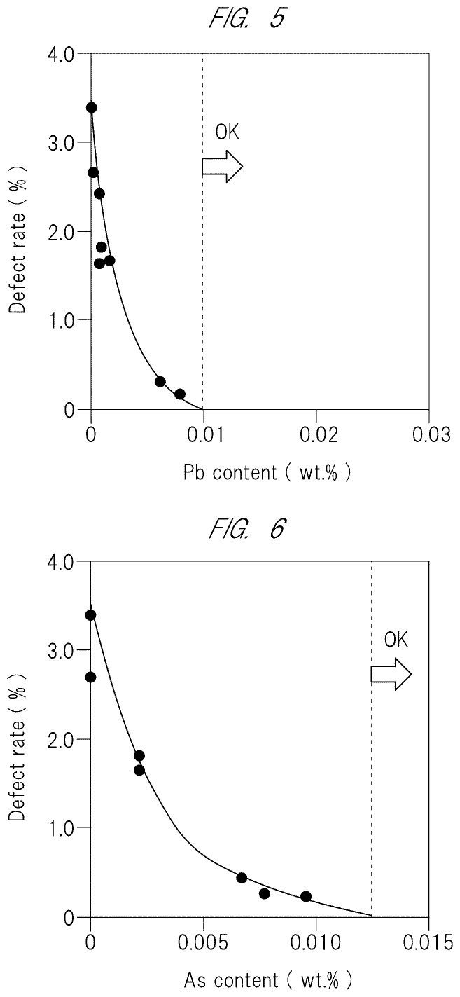

By adding Pb to the solder at 0.01 to 0.09 wt %, it is possible to suppress the wetting and spreading defect at the time of mass production. FIG. 5 illustrates a relationship between the Pb content and the occurrence rate of the wetting and spreading defect of the solder at the time of mass production. The vertical axis of the graph illustrated in FIG. 5 represents the occurrence rate of the wetting and spreading defect of the solder, and the horizontal axis represents the Pb content. As illustrated in FIG. 5, the defect occurrence rate decreases as the Pb content increases, and the wetting and spreading defect is suppressed at 0.01 wt % or more. On the other hand, when Pb is added at more than 0.09 wt %, Pb segregates in the vicinity of the interface of the bonding portion at the time of bonding, and thus there is a risk that the grain boundary fracture of the solder parent phase and the fracture of the interface of the bonding portion are accelerated due to thermal shock and the power cycle, thereby impairing reliability.

In addition, the solder of the present embodiment may contain As at a content of 0.0125 to 0.02 wt % in addition to Cu of 3 to 9 wt %, Sb of 6.7 to 9.6 wt %, and Sn.

By adding As to the solder at 0.0125 to 0.02 wt %, it is possible to suppress the wetting and spreading defect at the time of mass production. FIG. 6 illustrates a relationship between the As content and the occurrence rate of the wetting and spreading defect of the solder at the time of mass production. The vertical axis of the graph illustrated in FIG. 6 represents the occurrence rate of the wetting and spreading defect of the solder, and the horizontal axis represents the As content. As illustrated in FIG. 6, the defect occurrence rate decreases as the As content increases, and the wetting and spreading defect is suppressed at 0.0125 wt % or more. On the other hand, when As is added at more than 0.02 wt %, As segregates in the vicinity of the interface of the bonding portion at the time of bonding, and thus there is a risk that the grain boundary fracture of the solder parent phase and the fracture of the interface of the bonding portion may be accelerated due to thermal shock and the power cycle, thereby impairing reliability.

In addition, In (indium), Si (silicon), Au (gold), or Zn (zinc) may be added to the solder of the present embodiment at a predetermined concentration as described below.

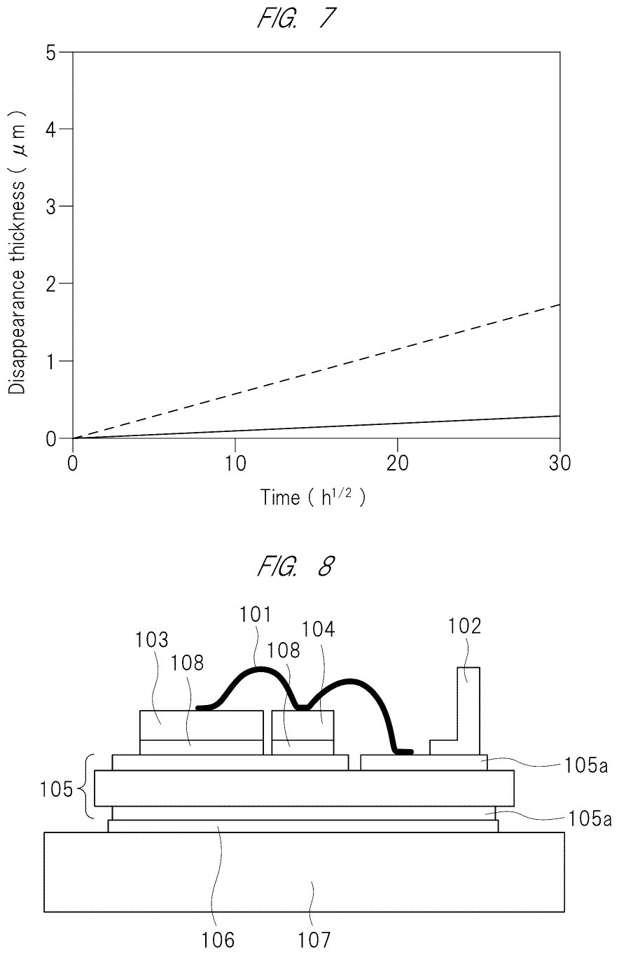

By adding In to the solder of the present embodiment at 0.01 to 0.45 wt %, In replaces Sn and enters the Cu₆Sn₅ or (Cu, Ni)₆Sn₅ compound layer formed adjacent to the Ni-based electrode of the semiconductor element. As a result, the compound adjacent to the Ni-based electrode turns into a Cu₆(Sn, In)₅ or (Cu, Ni)₆(Sn, In)₅ compound to increase in strength, thereby making it possible to improve the reliability of the solder against thermal shock. At this time, since the solder parent phase itself does not harden unlike the case where Sb is added at more than 9.6 wt %, it does not lead to cracking of the semiconductor element. On the other hand, when In is added at more than 0.45 wt %, as illustrated in FIG. 7, the solder is likely to react with the Ni-based electrode under high temperature of 150° C. or higher and the Ni electrode is likely to disappear, and thus there is a risk that the important heat resistance may be impaired. The vertical axis of the graph in FIG. 7 represents the disappearance thickness of the Ni electrode, and the horizontal axis represents the holding time (unit: h^{1/2}) at 200° C. In FIG. 7, the graph in the case without the addition of In is indicated by a solid line, and the graph in the case with the addition of In at more than 0.45 wt % is indicated by a broken line.

In addition, by adding Si to the solder of the present embodiment at 0.001 to 0.1 wt %, even when the solder is exposed to high temperature of 150° C. or higher after the semiconductor element is bonded, Si is preferentially oxidized and Sn which is the main component of the solder can be suppressed from being oxidized, and it is thus possible to suppress the deterioration of the solder bonding portion. Also, the addition of Si at less than 0.001 wt % is insufficient to suppress Sn from being oxidized. On the other hand, when Si is added at more than 0.1 wt %, since Si oxide formed on the surface of the solder melted at the time of solder bonding inhibits the wettability of the solder, it leads to the wetting and spreading defect.

In addition, by adding Au to the solder of the present embodiment at 0.001 to 0.09 wt %, Au replaces Cu and enters the Cu₆Sn₅ or (Cu, Ni)₆Sn₅ compound layer formed adjacent to the Ni-based electrode of the semiconductor element. As a result, a (Cu, Au)₆Sn₅ or (Cu, Ni, Au)₆Sn₅ compound is generated to increase in strength, thus making it possible to improve the reliability of the solder against thermal shock. At this time, since the solder itself does not harden unlike the case where Sb is added at more than 9.6 wt %, it does not lead to cracking of the semiconductor element. On the other hand, when Au is added at more than 0.09 wt %, an intermetallic compound mainly made of Au precipitates inside the solder after bonding and the solder hardens, and thus there is a risk that the semiconductor element may be cracked.

Also, by adding Zn to the solder of the present embodiment at 0.001 to 0.1 wt %, Zn replaces Cu and enters the Cu₆Sn₅ or (Cu, Ni)₆Sn₅ compound layer formed adjacent to the Ni-based electrode of the semiconductor element. As a result, a (Cu, Zn)₆Sn₅ or (Cu, Ni, Zn)₆Sn₅ compound is generated to increase in strength, thereby making it possible to improve the reliability of the solder against thermal shock. At this time, since the solder itself does not harden unlike the case where Sb is added at more than 9.6 wt %, it does not lead to cracking of the semiconductor element. On the other hand, when Zn is added at more than 0.1 wt %, Zn oxide formed on the surface of the solder melted at the time of bonding may inhibit the wettability of the solder.

### EXAMPLES

Hereinafter, examples in which the present invention was applied to a power semiconductor module will be described with reference to FIG. 8 and Tables 1 and 2. The examples were based on an experiment performed by the inventors by preparing the power semiconductor module described below.

First, the power semiconductor module illustrated in FIG. 8 was fabricated. In the present embodiment, semiconductor elements 103 and 104 each having an Ni-based electrode with a thickness of 0.6 μm were bonded using a solder sheet onto a ceramic substrate 105 having Cu wiring 105a on upper and lower surfaces of an AlN (aluminum nitride) substrate. An IGBT was formed in the semiconductor element 103 and a diode was formed in the semiconductor element 104. The semiconductor elements 103 and 104 and the ceramic substrate 105 were boned to each other with a solder 108. Subsequently, a bonding wire 101 was crimped to each of the semiconductor elements 103 and 104 and the ceramic substrate 105, and then the lower surface of the ceramic substrate 105 was bonded to a base 107 with a solder 106 made of Sn-10 wt % Sb. Thereafter, a Cu terminal 102 was ultrasonically bonded onto the Cu wiring 105a of the AlN substrate, thereby fabricating the power semiconductor module.

The inventors conducted a solder wetting and spreading defect test, a high temperature holding test, and a temperature cycle test by using solders having compositions illustrated in each of Examples 1 to 21 in Table 1 and Comparative Examples 1 to 17 in Table 2 as the solder 108 (solder sheet) constituting the power semiconductor module, and made a total judgment.

TABLE 1

| | | Wetting | | | | |
|---|---|---|---|---|---|---|
| | | and | High temperature | | | |
| | | spreading | holding test | | Temperature | |
| Example | Solder composition (wt. %) | defect | 150° C. | 170° C. | cycle test | Total |
| 1 | Sn-6.7~9.6Sb-3~9Cu-0.004~0.01Fe | ◯ | ◯ | ◯ | ◯ | ◯ |
| 2 | Sn-6.7~9.6Sb-3~9Cu-0.004~0.01Fe-0.01~0.45In | ◯ | ◯ | ◯ | ◯ | ◯ |
| 3 | Sn-6.7~9.6Sb-3~9Cu-0.004~0.01Fe-0.001~0.1Si | ◯ | ◯ | ◯ | ◯ | ◯ |
| 4 | Sn-6.7~9.6Sb-3~9Cu-0.004~0.01Fe-0.001~0.9Au | ◯ | ◯ | ◯ | ◯ | ◯ |
| 5 | Sn-6.7~9.6Sb-3~9Cu-0.004~0.01Fe-0.001~0.1Zn | ◯ | ◯ | ◯ | ◯ | ◯ |
| 6 | Sn-6.7~9.6Sb-3~9Cu-0.002~0.04Bi | ◯ | ◯ | ◯ | ◯ | ◯ |
| 7 | Sn-6.7~9.6Sb-3~9Cu-0.002~0.04Bi-0.01~0.45In | ◯ | ◯ | ◯ | ◯ | ◯ |
| 8 | Sn-6.7~9.6Sb-3~9Cu-0.002~0.04Bi-0.001~0.1Si | ◯ | ◯ | ◯ | ◯ | ◯ |
| 9 | Sn-6.7~9.6Sb-3~9Cu-0.002~0.04Bi-0.001~0.09Au | ◯ | ◯ | ◯ | ◯ | ◯ |
| 10 | Sn-6.7~9.6Sb-3~9Cu-0.002~0.04Bi-0.001~0.1Zn | ◯ | ◯ | ◯ | ◯ | ◯ |
| 11 | Sn-6.7~9.6Sb-3~9Cu-0.01~0.09Pb | ◯ | ◯ | ◯ | ◯ | ◯ |
| 12 | Sn-6.7~9.6Sb-3~9Cu-0.01~0.09Pb-0.01~0.45In | ◯ | ◯ | ◯ | ◯ | ◯ |
| 13 | Sn-6.7~9.6Sb-3~9Cu-0.01~0.09Pb-0.001~0.1Si | ◯ | ◯ | ◯ | ◯ | ◯ |
| 14 | Sn-6.7~9.6Sb-3~9Cu-0.01~0.09Pb-0.001~0.09Au | ◯ | ◯ | ◯ | ◯ | ◯ |
| 15 | Sn-6.7~9.6Sb-3~9Cu-0.01~0.09Pb-0.001~0.1Zn | ◯ | ◯ | ◯ | ◯ | ◯ |
| 16 | Sn-6.7~9.6Sb-3~9Cu-0.0125~0.02As | ◯ | ◯ | ◯ | ◯ | ◯ |
| 17 | Sn-6.7~9.6Sb-3~9Cu-0.0125~0.02As-0.01~0.45In | ◯ | ◯ | ◯ | ◯ | ◯ |
| 18 | Sn-6.7~9.6Sb-3~9Cu-0.0125~0.02As-0.001~0.1Si | ◯ | ◯ | ◯ | ◯ | ◯ |
| 19 | Sn-6.7~9.6Sb-3~9Cu-0.0125~0.02As- | ◯ | ◯ | ◯ | ◯ | ◯ |
| | 0.001~0.09Au | | | | | |
| 20 | Sn-6.7~9.6Sb-3~9Cu-0.0125~0.02As-0.001~01Zn | ◯ | ◯ | ◯ | ◯ | ◯ |
| 21 | Sn-6.7~9.6Sb-3~9Cu-0.004~0.01Fe- | ◯ | ◯ | ◯ | ◯ | ◯ |
| | 0.002~0.04Bi-0.01~0.09Pb-0.0125~0.02As | ◯ | ◯ | ◯ | ◯ | ◯ |

| | | Wetting | | | | |
|---|---|---|---|---|---|---|
| | | and | High temperature | | | |
| Comparative | | Spreading | holding test | | Temperature | |
| Example | Solder composition (wt. %) | defect | 150° C. | 170° C. | cycle test | Total |
| 1 | Sn-6.7~9.6Sb-3~9Cu | X | ◯ | ◯ | ◯ | X |
| 2 | Sn-6.7~9.6Sb-3~9Cu-0.004~0.01F-3.0In | ◯ | X | X | ◯ | X |
| 3 | Sn-6.7~9.6Sb-3~9Cu-0.004~0.01F-0.3Si | X | ◯ | ◯ | ◯ | X |
| 4 | Sn-6.7~9.6Sb-3~9Cu-0.004~0.01F-0.2Au | ◯ | ◯ | ◯ | X | X |
| 5 | Sn-6.7~9.6Sb-3~9Cu-0.004~0.01F-0.2Zn | X | ◯ | ◯ | ◯ | X |
| 6 | Sn-6.7~9.6Sb-3~9Cu-0.002~0.04Bi-3.0In | ◯ | X | X | ◯ | X |
| 7 | Sn-6.7~9.6Sb-3~9Cu-0.002~0.04Bi-0.3Si | X | ◯ | ◯ | ◯ | X |
| 8 | Sn-6.7~9.6Sb-3~9Cu-0.002~0.04Bi-0.2Au | ◯ | ◯ | ◯ | X | X |
| 9 | Sn-6.7~9.6Sb-3~9Cu-0.002~0.04Bi-0.2Zn | X | ◯ | ◯ | ◯ | X |
| 10 | Sn-6.7~9.6Sb-3~9Cu-0.01~0.09Pb-3.0In | ◯ | X | X | ◯ | X |
| 11 | Sn-6.7~9.6Sb-3~9Cu-0.01~0.09Pb-0.3Si | X | ◯ | ◯ | ◯ | X |
| 12 | Sn-6.7~9.6Sb-3~9Cu-0.01~0.09Pb-0.2Au | ◯ | ◯ | ◯ | X | X |
| 13 | Sn-6.7~9.6Sb-3~9Cu-0.01~0.09Pb-0.2Zn | X | ◯ | ◯ | ◯ | X |
| 14 | Sn-6.7~9.6Sb-3~9Cu-0.0125~0.02As-3.0In | ◯ | X | X | ◯ | X |
| 15 | Sn-6.7~9.6Sb-3~9Cu-0.0125~0.02As-0.3Si | X | ◯ | ◯ | ◯ | X |
| 16 | Sn-6.7~9.6Sb-3~9Cu-0.0125~0.02As-0.2Au | ◯ | ◯ | ◯ | X | X |
| 17 | Sn-6.7~9.6Sb-3~9Cu-0.0125~0.02As-0.2Zn | X | ◯ | ◯ | ◯ | X |

Here, in the fabrication of the power semiconductor module, the solder was evaluated as ◯ when the wetting and spreading defect in which 5% or more of the bonding area of the semiconductor element was not wet was 0.5% or less. In addition, a temperature cycle test between −55° C. and 175° C. was performed up to 1000 cycles on the fabricated power semiconductor module, and the solder was evaluated as ◯ when development of solder crack in the bonding portion of the semiconductor element or cracking of the bonding portion of the semiconductor element was less than 30% of the area of the bonding portion. In addition, a high temperature holding test was performed at 150° C. and 175° C. for 1000 hours, and the solder was evaluated as ◯ when the residual thickness of the Ni-based electrode of the semiconductor element was 0.1 μm or more.

Examples 1 to 21 illustrated in Table 1 had the solder composition of the present embodiment described above. In the cases of Examples 1 to 21, the total judgment was ◯ for each example from the results of the wetting and spreading defect of the solder, the high temperature holding test, and the temperature cycle test.

On the other hand, Comparative Examples 1 to 17 had a different solder composition from that of the present embodiment described above. When the solder of any of Comparative Examples 1 to 17 was used, the wettability and spreadability judgment was x or either the high temperature holding test or the temperature cycle test was x even when the wettability and spreadability judgment was ◯, and there were no solders from which good reliability was obtained.

### (Effects of Present Embodiment)

The solder of the present embodiment contains Cu at a content of 3 to 9 wt % and Sb at a content of 6.7 to 9.6 wt %, and further contains one or a plurality of types of elements among Fe of 0.004 to 0.01 wt %, Bi of 0.002 to 0.04 wt %, Pb of 0.01 to 0.09 wt %, and As of 0.0125 to 0.02 wt %. By adding one or a plurality of types of elements selected from Fe of 0.004 to 0.01 wt %, Bi of 0.002 to 0.04 wt %, Pb of 0.01 to 0.09 wt %, and As of 0.0125 to 0.02 wt % to the solder, the wetting and spreading defect is more likely to be suppressed.

Namely, with the solder according to the present embodiment, it is possible to improve the connection reliability of solder connection of the semiconductor device under a high temperature environment and to reduce the wetting and spreading defect of the solder.

### Second Embodiment

A semiconductor device in which a semiconductor element having an Ni-based electrode is bonded to a substrate by using the solder of the first embodiment will be described below. The semiconductor device is similar to that illustrated in FIG. 8.

Namely, here, the semiconductor elements 103 and 104 each having, on the lower surface, an electrode mainly made of Ni such as an Ni electrode or an Ni—V (nickel-vanadium) electrode formed by sputtering, vapor deposition, or the like or Ni—P (nickel-phosphorus) plating or Ni—B (nickel-boron) plating formed by electroless plating are prepared. Subsequently, the semiconductor elements 103 and 104 are bonded to the substrate (for example, the ceramic substrate 105) with the solder 108 of the first embodiment described above. In this way, the semiconductor device of the present embodiment is substantially completed.

Here, it is possible to obtain the semiconductor device capable of suppressing the wetting and spreading defect of the solder 108 and the reaction between the Ni-based electrode and the solder under high temperature of 150° C. or higher and having high reliability against thermal shock and the power cycle. At this time, the semiconductor elements 103 and 104 may be made of any semiconductor such as SiC (silicon carbide), GaN (gallium nitride), or the like other than Si (silicon) and the effect can be obtained as long as the semiconductor elements have the Ni-based electrode. In addition, even when a film for supporting solder wetting such as Au, Ag (silver), or Pd is provided on the surfaces of the semiconductor elements 103 and 104, the similar effect can be obtained when performing solder bonding.

Although the invention made by the inventors of this application has been specifically described based on the embodiments thereof, the present invention is not limited to the above embodiments, and various modifications are possible without departing from the gist of the present invention.

### INDUSTRIAL APPLICABILITY

The present invention can be widely used for a solder and a semiconductor device using the same.

### REFERENCE SIGNS LIST

1, 106 solder
2, 103, 104 semiconductor element
3 substrate
4 Ni-based electrode
5 electrode
12 parent phase
13 compound layer
101 bonding wire
102 Cu terminal
105 ceramic substrate
105a Cu wiring
107 base

1. A solder containing Cu at a content of 3 to 9 wt %, Sb at a content of 6.7 to 9.6 wt %, and Sn, and added with one or a plurality of types of elements among Fe of 0.004 to 0.01 wt %, Bi of 0.002 to 0.04 wt %, Pb of 0.01 to 0.09 wt %, and As of 0.0125 to 0.02 wt %.

2. The solder according to claim 1,
wherein Fe is added at 0.004 to 0.01 wt %.

3. The solder according to claim 1,
wherein Bi is added at 0.002 to 0.04 wt %.

4. The solder according to claim 1,
wherein Pb is added at 0.01 to 0.09 wt %.

5. The solder according to claim 1,
wherein As is added at 0.0125 to 0.02 wt %.

6. The solder according to claim 1,
wherein In is added at 0.01 to 0.45 wt %.

7. The solder according to claim 1,
wherein Si is added at 0.001 to 0.1 wt %.

8. The solder according to claim 1,
wherein Au is added at 0.001 to 0.09 wt %.

9. The solder according to claim 1,
wherein Zn is added at 0.001 to 0.1 wt %.

10. A semiconductor device in which an Ni-based electrode provided in a semiconductor element is bonded with the solder according to claim 1.
